(19) United States
(12) Patent Application Publication
(10) Pub. No.: US 2018/0026170 A1
(43) Pub. Date: Jan. 25, 2018

(54) THERMOELECTRIC MATERIAL AND METHOD FOR PRODUCING THERMOELECTRIC MATERIAL

(71) Applicant: TOHOKU UNIVERSITY, Sendai-shi (JP)

(72) Inventors: Yuzuru MIYAZAKI, Sendai-shi (JP); Kei HAYASHI, Sendai-shi (JP); Kunio YUBUTA, Sendai-shi (JP); Haruki HAMADA, Sendai-shi (JP); Mika SATO, Sendai-shi (JP)

(73) Assignee: TOHOKU UNIVERSITY, Sendai-shi (JP)

(21) Appl. No.: 15/445,570

(22) Filed: Feb. 28, 2017

(30) Foreign Application Priority Data
Jul. 25, 2016 (JP) 2016-145712

(51) Int. Cl. H01L 35/14; H01L 35/28; H01L 35/34

(52) U.S. Cl. CPC H01L 35/14; H01L 35/34; H01L 35/28

(57) ABSTRACT

A thermoelectric material having improved thermoelectric properties and a method for producing the thermoelectric material are provided. The thermoelectric material contains (Mn_{1-x-y}VₓFe_{y})Si_{γ} (0.012≦x≦0.045, 0≦y≦0.06, 1.7≦γ≦1.8) and is produced by homogenously melting the raw materials including Mn, Si, and V mixed to a composition of the thermoelectric material, and then solidifying the melted raw materials at a cooling rate of 13 K/hour or less.

### TECHNICAL FIELD

The present invention relates to a thermoelectric material and a method for producing the thermoelectric material.

### BACKGROUND ART

Conventional manganese silicide-based thermoelectric materials MnSi_{γ} (where 1.7≦γ≦1.8)wherein the ab surface of each crystal grain is oriented into a direction, include those in which Si elements are partially substituted with at least one type of element selected from among IIIb group elements, IVb group elements, and lanthanoid elements, and those in which Mn elements are partially substituted with at least one type of element selected from among Va group elements, VIa group elements, VIIa group elements, VIIIa group elements, and lanthanoid elements (for example, see Patent Document 1 or 2). These thermoelectric materials are excellent in thermoelectric properties and thermal shock resistance, for example, such that one of thermoelectric properties, the power factor S²σ (where S denotes the Seebeck coefficient, and σ denotes the electrical conductivity), of up to 2.22 mW/K²m is obtained at 500° C.

These thermoelectric materials are produced by melting raw materials by arc melting or the like, solidifying, and then further sintering as necessary by spark plasma sintering (SPS) or the like, wherein MnSi (manganese monosilicide) is precipitated in layers in the materials with a period of several tens of microns into the c-axis direction of MnSi_{γ}. The manganese monosilicide MnSi is a good P-type conductor having metallic properties. Its high electrical conductivity σ, its low Seebeck coefficient S, and its discontinuous atomic arrangement at the boundary lower the materials' figure of merit Z (obtained by dividing the power factor S²σ by the thermal conductivity κ).

Accordingly, a thermoelectric material Mn(Si₁₋ₓGeₓ)_{γ} (where 0.005≦x≦0.01) has been developed by partial substitution of 0.5 to 1.0 at % of Si elements with Ge, as a thermoelectric material with MnSi not precipitated in layers (for example, see Non-patent Document 1 or Patent Document 3). This thermoelectric material is produced by melting Mn and Si satisfying the stoichiometric composition of the base material, MnSi_{γ}, and Ge in an amount corresponding to that of “x”, and then cooling the resultant at a cooling rate of 1.5° C./minute or less for crystal growth. The thermoelectric material exhibits the power factor S²σ of up to about 1.6 mW/K²m.

In addition, the present inventors have reported that partial substitution of Mn elements of a thermoelectric material MnSi_{γ} with elements having a valence number lower than that of Mn (for example, chromium), results in doped holes, improved conductivity, and increased power factor S²σ (for example, see Non-patent Document 2). Moreover, the thermoelectric material MnSi_{γ} is incommensurate composite crystal composed of 2 types of subsystems, [Mn] and [Si] that share the tetragonal a-b axis and differ in the length of the c axis.

### PRIOR ART DOCUMENTS

### Patent Documents

Patent Document 1: JP Patent Publication (Kokai) No. 2009-231638 A

Patent Document 2: JP Patent Publication (Kokai) No. 2007-42963 A

Patent Document 3: JP Patent Publication (Kokai) No. 2007-235083 A

### Non-Patent Documents

Non-Patent Document 1: I. Aoyama et al, “Effects of Ge Doping on Micromorphology of MnSi in MnSi_{˜}1.7 and on Their Thermoelectric Transport Properties”, Japanese Journal of Applied Physics, 2005, 44, 8562

Non-Patent Document 2: Y. Kikuchi et al, “Enhanced Thermoelectric Performance of a Chimney-Ladder (Mn₁₋ₓCrₓ)Si_{γ} (γ˜1.7) Solid Solution”, Japanese Journal of Applied Physics, 2012, 51, 085801

### SUMMARY OF THE INVENTION

### Problems to be Solved by the Invention

The thermoelectric material described in Patent Document 1 or 2 is problematic in that MnSi precipitated in layers affects to lower the thermoelectric properties. Furthermore, the thermoelectric material described in Non-patent Document 1 or Patent Document 3 causes no layered precipitation of MnSi so as to inhibit the figure of merit Z from decreasing due to the precipitation, however, the material is problematic in that the amount of Ge to be substituted is limited, and thus further improvement in thermoelectric properties cannot be expected.

The present invention has been achieved, noting such problems, and an objective of the present invention is to provide a thermoelectric material with improved thermoelectric properties and a method for producing the thermoelectric material.

### Solutions to the Problems

The present inventors have discovered for the first time that the layered precipitation of MnSi can be inhibited not by partial substitution of Si elements, but by partial substitution of Mn elements with other elements, and thus have completed the present invention.

Specifically, the thermoelectric material according to the present invention is characterized by containing (Mn_{1-x-y}VₓFe_{y})Si_{γ} (0.012≦x≦0.045, 0≦y≦0.06, and 1.7≦γ≦1.8).

The thermoelectric material according to the present invention is characterized in that the precipitation of MnSi in layers can be inhibited by partial substitution of Mn elements with V (vanadium). Hence, this can inhibit the figure of merit Z from decreasing due to the layered precipitation, and can improve the thermoelectric properties. Furthermore, V has a valence number lower by 2 and an atomic radius higher than those of Mn, so that hole carriers can be introduced sufficiently even in the case of substitution with a trace amount thereof ranging from about 1.2 to 4.5 at %. Therefore, the power factor S²σ can be increased and the thermoelectric properties can further be improved. In this manner, the thermoelectric material according to the present invention can lead to more improved thermoelectric properties by partial substitution of not Si elements, but Mn elements alone with V.

Moreover, when Mn elements are partially substituted with V until the precipitation of MnSi in layers disappears, hole carriers may be excessive. In such a case, whereas the electrical conductivity σ is improved, the Seebeck coefficient S decreases. Hence, Fe is added for partial substitution of Mn elements with Fe having a valence number higher by 1 than that of Mn, so that increases in hole carrier can be inhibited by electron doping. Accordingly, the Seebeck coefficient S is increased, the power factor S²σ can be increased, and the thermoelectric properties can be improved. The thermoelectric material according to the present invention can enhance thermoelectric properties in the case of particularly 0.025≦x≦0.045, and 0.01≦y≦0.045.

The thermoelectric material according to the present invention preferably has a power factor S²σ of 1.8 mW/K²m or more at 700K to 900K, a power factor S²σ of 1.2 mW/K²m or more at 300K to 1000K. The thermoelectric material has further preferably has a power factor S²σ of 2.2 mW/K²m or more at 700K to 900K, and a power factor S²σ of 1.4 mW/K²m or more at 300K to 1000K. Furthermore, a dimensionless figure of merit ZT (here, “T” denotes the absolute temperature) at 800K to 900K is preferably 0.55 or more, and a dimensionless figure of merit ZT at 300K to 1000K is preferably 0.15 or more. In these cases, the thermoelectric material is excellent in particularly thermoelectric properties.

The method for producing a thermoelectric material according to the present invention involves a melting step for homogeneously melting raw materials including Mn, Si and V mixed to a composition of the above thermoelectric material, and a solidifying step for solidifying the thus melted raw materials at a cooling rate of 13K/hour or less. When the thermoelectric material having a composition including Fe is produced, raw materials including Mn, Si, V and Fe are homogeneously melted in the melting step.

With the method for producing a thermoelectric material according to the present invention, the thermoelectric material according to the present invention can be produced appropriately. The method for producing a thermoelectric material according to the present invention involves solidifying melted raw materials including Mn, Si and V at a cooling rate of 13K/hour or less, so as to be able to inhibit the layered precipitation of MnSi. Moreover, hole carriers can also be introduced by partial substitution with V. Accordingly, the thermoelectric material with improved thermoelectric properties can be obtained. When raw materials include Fe, the thermoelectric material with improved thermoelectric properties can be obtained by partial substitution with V and Fe. In particular, the cooling rate is preferably 1.5K/hour or less. In this case, further improved thermoelectric properties can be obtained. In addition, the “cooling rate” as used herein refers to a cooling rate when melted raw materials are solidified, and specifically refers to a rate of cooling performed within a predetermined temperature range including temperatures for solidification.

### Effects of the Invention

According to the present invention, a thermoelectric material with improved thermoelectric properties and a method for producing the thermoelectric material can be provided.

### BRIEF DESCRIPTION OF THE DRAWINGS

FIG. 1 shows the XRD pattern of each composition when the value of “x” of the thermoelectric material (y=0) according to an embodiment of the present invention is varied from 0 to 0.060.

FIG. 2 shows XRD patterns of the thermoelectric material (y=0) according to the embodiment of the present invention, which was produced with the cooling times of 8 hours (cooling rate: 12.5K/hour), 24 hours (cooling rate: 4.2K/hour), and 100 hours (cooling rate: 1K/hour), respectively.

FIG. 3 shows (a) SEM (scanning electron microscope) photograph, (b) EDS (energy dispersive X-ray analysis) map of Mn, and (c) EDS map of Si of samples having a composition of x=0, and, (d) SEM photograph, (e) EDS map of Mn, and (f) EDS map of Si of samples having a composition of x=0.020 of the thermoelectric material (y=0) according to the embodiment of the present invention, which was produced with the cooling time of 100 hours (cooling rate: 1K/hour).

FIG. 4 shows an SEM photograph of samples having a composition of x=0.020 of the thermoelectric material (y=0) according to the embodiment of the present invention, which was produced with the cooling time of 8 hours (cooling rate: 12.5K/hour).

FIG. 5 shows graphs indicating the temperature dependence of (a) Seebeck coefficient S, (b) electrical conductivity σ, (c) power factor S²σ, and (d) dimensionless figure of merit ZT of samples (melt grown) having compositions of x=0 and x=0.020 of the thermoelectric material (y=0) according to the embodiment of the present invention, which was produced with the cooling time of 100 hours (cooling rate: 1K/hour), as well as, comparative samples (SPS) prepared by spark plasma sintering (SPS) so as to have compositions of x=0 and x=0.020.

FIG. 6 shows graphs indicating the temperature dependence of (a) Seebeck coefficient S, (b) electrical conductivity σ, (c) power factor S²σ of a sample (8 h) having a composition of x=0.020 of the thermoelectric material (y=0) according to the embodiment of the present invention, which was produced with the cooling time of 8 hours (cooling rate: 12.5K/hour), as well as, a sample (100 h) having a composition of x=0.020 of the same, which was produced with the cooling time of 100 hours (cooling rate: 1K/hour).

FIG. 7 is a graph indicating the temperature dependence of the power factor S²σ when the value of “y” of the thermoelectric material (x=0.03) according to the embodiment of the present invention was varied from 0 to 0.05.

### EMBODIMENTS OF THE INVENTION

Hereinafter, the embodiment of the present invention is explained below on the basis of drawings.

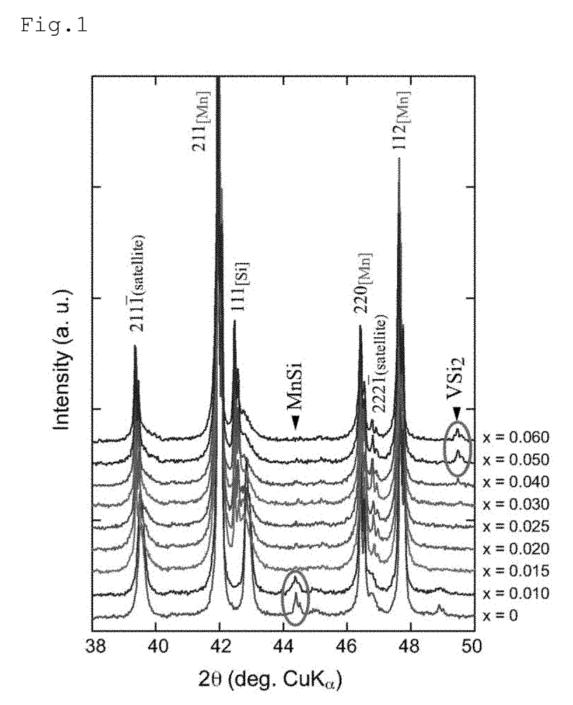

FIG. 1 to FIG. 6 show the thermoelectric material according to the embodiment of the present invention.

The thermoelectric material according to the embodiment of the present invention is produced by the method for producing a thermoelectric material of the present invention and contains (Mn_{1-x-y}VₓFe_{y})Si_{γ} (0.012≦x≦0.045, 0≦y≦0.06, and 1.7≦γ≦1.8).

The method for producing a thermoelectric material according to the embodiment of the present invention involves homogeneously melting raw materials including Mn, Si and V mixed to a desired composition. When a thermoelectric material having a composition including Fe is produced, Fe is also melted homogeneously as a raw material. Next, the melted raw materials are solidified at a cooling rate of 13K/hour or less. Thus, the thermoelectric material according to the embodiment of the present invention can be obtained.

Next, the effects are as explained below.

With the use of the method for producing a thermoelectric material according to the embodiment of the present invention, melted raw materials including Mn, Si, and V are gradually cooled at a cooling rate of 13K/hour or less for solidification, and then Mn elements are partially substituted with V (vanadium), so that the layered precipitation of MnSi can be inhibited. Hence, a decrease in figure of merit Z due to the layered precipitation is inhibited, so that the thermoelectric properties can be improved. Moreover, V has a valence number lower by 2 and an atomic radius larger than those of Mn, so that hole carriers can be sufficiently introduced even via substitution with a trace amount thereof ranging from about 1.2 to 5 at %. Accordingly, the power factor S²σ can be increased, and the thermoelectric properties can be further improved. As described above, partial substitution of not Si elements, but Mn elements alone with V enables to obtain the thermoelectric material with improved thermoelectric properties according to the embodiment of the present invention.

Moreover, when substitution with V leads to excessive hole carriers, Fe is added for partial substitution of Mn elements with Fe, and then electrons are doped, so as to be able to inhibit increase in hole carriers. Therefore, the Seebeck coefficient S is increased, the power factor S²σ can be increased, and thus thermoelectric properties can be improved.

### EXAMPLE 1

A thermoelectric material having the composition of (Mn₁₋ₓVₓ)Si_{γ} (y=0) was produced, and examined for crystal structure, fine structure, and thermoelectric properties. As raw materials, granular Mn having a purity of 99.99% and a grain size of 2 mm to 5 mm, granular Si having a purity of 99.999% and a grain size of 2 mm to 5 mm, and powdered V having a purity of 99.9% and a grain size of 300 μm were used. Samples of the thermoelectric material were produced as follows.

First, raw materials were mixed in predetermined amounts, respectively, and then subjected to arc melting by which melting and solidification were repeated, so that a solid homogenized product was obtained. Next, the thus obtained homogenized product was pulverized into grains, sealed within a silica tube, and then melted by heating to 1200° C. (1473K). The temperature was maintained at 1200° C. for 8 hours, the resultant was cooled for 8 to 100 hours to 1100° C. (1373K) (cooling rate: 12.5 to 1K/hour) for solidification. Subsequently, the resultant was cooled for 24 hours to room temperature (RT). In this manner, samples of the clumped thermoelectric material with γ=1.740 and x=0 to 0.060 (hereinafter, referred to as “melt grown”) were produced.

In addition, for comparison, raw materials were melted by arc melting and then solidified, powdered, and then compressed by spark plasma sintering (SPS), thereby producing a comparative sample (hereinafter, referred to as “SPS”). The comparative sample is characterized by γ=1.740, and x=0 and 0.020.

### X-Ray Diffraction

Melt grown samples subjected to 100 hours of cooling (cooling rate: 1K/hour) were subjected to crystal structure analysis by an X-ray diffraction method, wherein the value of “x” was varied from 0 to 0.060. Upon X-ray diffraction (XRD), measurement was performed by “D8 ADVANCE” (Bruker AXS) using a CuKα line. The thus obtained XRD pattern is shown in FIG. 1.

As shown in FIG. 1, peaks derived from a Mn subsystem (peaks 211, 220, and 112), a peak derived from a Si subsystem (peak 111), and satellite peaks (peaks 2111 and 2221) were confirmed. Of these peaks, the peak derived from the Si subsystem and the satellite peaks were confirmed to come closer to the lower angle side and be sharp peaks in the case of x=0.015 or more. It was confirmed that peaks corresponding to MnSi were observed in the case of x=0 and x=0.010, but the peaks disappeared and no such peaks were observed in the case of x=0.015 or higher. It was also confirmed that peaks corresponding to VSi₂ were observed in the case of x=0.050 and x=0.060, however, the peaks disappeared and no such peaks were observed in the case of x=0.040 or lower. These results indicate that the precipitation of MnSi in layers and the precipitation of VSi₂ are inhibited in the case of x=0.012 to 0.045, resulting in the composition of the single-phase (Mn₁₋ₓVₓ)Si_{γ} alone.

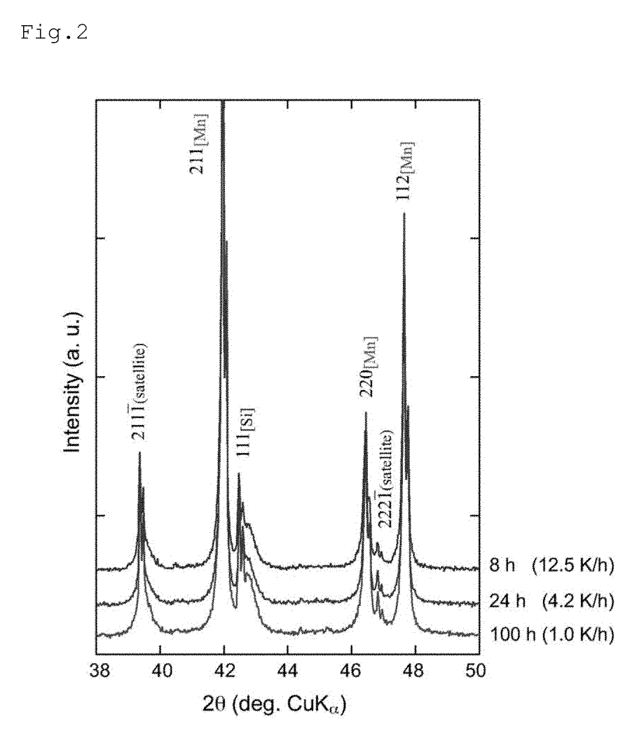

Next, melt grown samples with x=0.020 were subjected to crystal structure analysis by an X-ray diffraction method in a manner similar to that in FIG. 1, when the time for cooling from 1200° C. (1473K) to 1100° C. (1373K) had been varied to 8 hours (cooling rate: 12.5K/hour), 24 hours (cooling rate: 4.2K/hour), and 100 hours (cooling rate: 1K/hour). The thus obtained XRD pattern is shown in FIG. 2.

As shown in FIG. 2, with any cooling time, no precipitation of MnSi in layers and no precipitation of VSi₂ were observed, confirming that the composition was composed of the single-phase (Mn₁₋ₓVₓ)Si_{γ} alone.

### Scanning Electron Microscopy and Energy-Dispersive X-Ray Spectroscopy

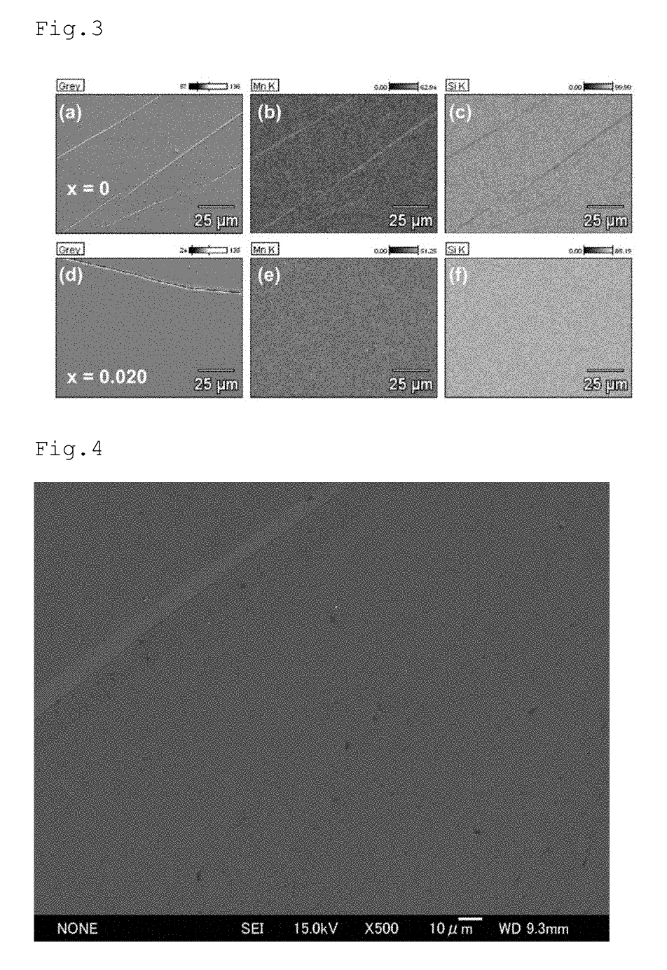

Melt grown samples with x=0 and x=0.020 in the case of 100 hours of cooling (cooling rate: 1K/hour) were observed under a scanning electron microscope (SEM), and subjected to energy-dispersive x-ray spectroscopy (EDS). Moreover, melt grown samples with x=0.020 in the case of 8 hours of cooling (cooling rate: 12.5K/hour) were observed under SEM. A scanning electron microscope “SU-8100” (Hitachi High-Technologies Corporation) was used for observation under SEM and measurement by EDS. The thus obtained SEM photograph of each sample and each EDS map are shown in FIG. 3 and FIG. 4.

As shown in FIG. 3(a) to (c), a plurality of lines composed of MnSi were confirmed at a cooling rate of 1K/hour and in the case of x=0; that is, MnSi_{1.740}. The MnSi had a thickness of about 500 nm, and precipitated in layers with a period of several tens of microns. In contrast, as shown in FIG. 3(d) to (f), a homogenous element distribution was exhibited at a cooling rate of 1K/hour and in the case of x=0.020; that is, (Mn_{0.980}V_{0.020}) Si_{1.740}, and no precipitation of MnSi in layers was confirmed.

Furthermore, as shown in FIG. 4, a linear crack (upper left in FIG. 4) was formed at a cooling rate of 12.5K/hour and in the case of x=0.020; that is, (Mn_{0.980}V_{0.020})Si_{1.740}, however, a homogenous element distribution was exhibited, and no precipitation of MnSi in layers was confirmed. The above results in FIG. 1 to FIG. 4 indicate that the precipitation of MnSi in layers can be inhibited by the partial substitution of Mn elements with V.

### Thermoelectric Properties

Melt grown samples with x=0 and x=0.020 in the case of 100 hours of cooling (cooling rate: 1K/hour) and SPS samples with x=0 and x=0.020 were measured for Seebeck coefficient, electrical conductivity and thermal conductivity. A thermal property measurement system “ZEM-3” (Advance Riko Inc.,) was used for measurement of Seebeck coefficient and electrical conductivity. In addition, a laser flash method thermal constant measurement system “TC-7000H” (Advance Riko Inc.,) was used for measuring thermal conductivity. Moreover, upon measurement of each of these thermoelectric properties, measurement was performed for SPS samples along the direction of compression by SPS, and for melt grown samples along the direction same as the compression direction for the corresponding SPS samples.

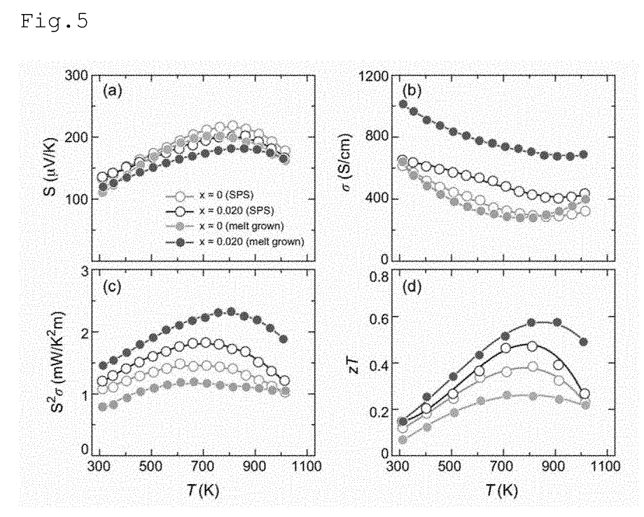

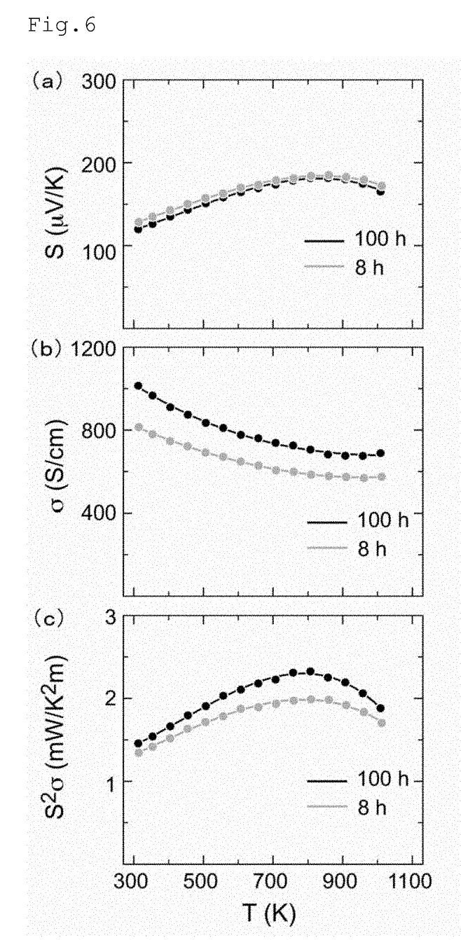

The temperature dependence of Seebeck coefficient S, electrical conductivity σ, power factor S²σ, and dimensionless figure of merit ZT (Z=S²σ/κ, where Z denotes the figure of merit, κ denotes the thermal conductivity, and T denotes the absolute temperature) of each sample found by measurement of the thermoelectric properties are shown in FIG. 5(a) to (d), respectively. As shown in FIG. 5(a), when x=0 and x=0.020 were compared, a slight decrease in Seebeck coefficient S due to partial substitution of Mn elements with V was confirmed for both melt grown samples and SPS samples. It was also confirmed that when the values of “x” are the same, melt grown samples exhibited Seebeck coefficient S slightly lower than those of SPS samples.

As shown in FIG. 5(b), both melt grown samples with x=0.020 and SPS samples with x=0.020 were confirmed to have electrical conductivity σhigher than those of the same with x=0. This may be due to introduction of hole carriers as a result of partial substitution of Mn elements with V. Moreover, in the case of x=0, melt grown samples and SPS samples were confirmed to have almost the same electrical conductivity σ, however, in the case of x=0.020, melt grown samples were confirmed to have electrical conductivity σ higher than those of SPS samples. This is considered that the precipitation of MnSi in layers can be effectively inhibited by solidification via slow cooling and partial substitution of Mn elements with V (vanadium).

As shown in FIG. 5(c), the power factor S²σ was confirmed to be the highest in the case of melt grown samples with x=0.020. This is because, unlike Seebeck coefficient S, electrical conductivity σ (see FIG. 5(b)) differed significantly due to the presence or the absence of substitution with V or the production method. This indicates that solidification via slow cooling and partial substitution of Mn elements with V lead to increases in power factor S²σ. However, when the amount of V to be added is excessively increased, hole carriers are excessively introduced, and thus the power factor S²σ can decrease. In addition, melt grown samples with x=0.020 shown in FIG. 5(c) exhibited the highest power factor S²σ of 2.4 mW/K²m at 800K, 2.2 mW/K²m or more at 700K to 900K, and 1.4 mW/K²m or more at 300K to 1000K.

As shown in FIG. 5(d), the dimensionless figure of merit ZT was confirmed to be the highest in the case of melt grown samples with x=0.020, similarly to power factor S²σ. This indicates that solidification via slow cooling and partial substitution of Mn elements with V lead to increases in dimensionless figure of merit ZT. In addition, the dimensionless figure of merit ZT at this time was 2 or more times that of melt grown samples with x=0, exhibited the highest value of 0.59 at 800K to 900K, about 0.50 or more at 700K to 1000K, and 0.15 or more at 300K to 1000K.

Next, melt grown samples with x=0.020 in the case of 8 hours of cooling (cooling rate: 12.5K/hour) were also measured for Seebeck coefficient, electrical conductivity, and thermal conductivity in a manner similar to that in FIG. 5. The temperature dependence of the thus measured Seebeck coefficient S, electrical conductivity σ, and power factor S²σ are shown in FIG. 6(a) to (c), respectively. In addition, FIG. 6 shows for comparison the results of melt grown samples with x=0.020 subjected to 100 hours of cooling (cooling rate: 1K/hour) shown in FIG. 5.

As shown in FIG. 6(a), the Seebeck coefficient S was confirmed to exhibit almost the same value even when the cooling time (cooling rate) was varied. As shown in FIG. 6(b), it was confirmed that the longer the cooling time (cooling rate was low), the higher the electrical conductivity σ. It is considered that since cracks were formed in the case of samples subjected to 8 hours of cooling (cooling rate: 12.5K/hour), as shown in FIG. 4, so that electrical conductivity σ decreased. As shown in FIG. 6(c), it was confirmed that the longer the cooling time (cooling rate was low), the higher the power factor S²σ, because of a significant difference in electrical conductivity σ (see FIG. 6(b)).

Based on the results in FIG. 2, FIG. 4 and FIG. 6, it can be said that the precipitation of MnSi in layers can be inhibited even in the case of 8 hours of cooling (cooling rate: 12.5K/hour), however, defects such as cracks or voids are caused to take place in such a case. Hence, the cooling time should be longer (the cooling rate should be lower) in order to improve the thermoelectric properties.

Moreover, samples in the case of 8 hours of cooling (cooling rate: 12.5K/hour) as shown in FIG. 6(c) exhibited the highest power factor S²σ of about 2.0 mW/K²m at 800K, 1.8 mW/K²m or more at 700K to 900K, and 1.2 mW/K²m or more at 300K to 1000K.

### EXAMPLE 2

A thermoelectric material having a composition of (Mn_{0.97-y}V_{0.03}Fe_{y})Si_{1.7} (x=0.03, γ=1.7) was produced, and then examined for thermoelectric properties. As raw materials, granular Mn having a purity of 99.99% and a grain size of 2 mm to 5 mm, granular Si having a purity of 99.999% and a grain size of 2 mm to 5 mm, powered V having a purity of 99.9% and a grain size of 300 μm, and powdered Fe having a purity of 99.9% and a grain size of 0.1 mm to 1.7 mm were used. Samples of the thermoelectric material were produced in a manner similar to that of Example 1. Cooling was performed for 100 hours (cooling rate: 1K/hour). Samples with y=0, 0.02, 0.03, 0.04, and 0.05 were produced.

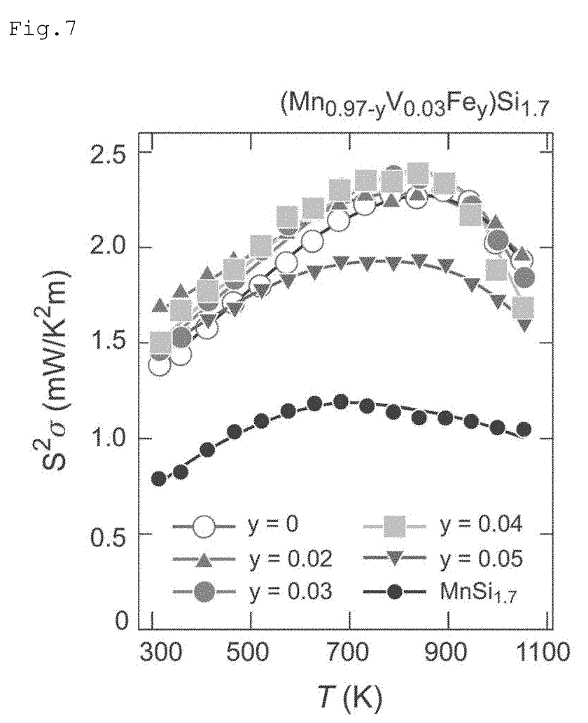

Each sample was measured for Seebeck coefficient and electrical conductivity in a manner similar to that of Example 1. For comparison, MnSi_{1.7} samples were also produced and measured similarly. The temperature dependence of the power factor S²σ found for each sample by measurement is shown in FIG. 7. As shown in FIG. 7, the power factor S²σ was confirmed to be high in the case of y=0 to 0.04. Particularly in the case of y=0.01 to 0.04, the power factor S²σ was confirmed to be somewhat higher than that of melt grown samples with x=0.020 in FIG. 5(c).

This can be interpreted as follows. First, in this Example, the amount of V was increased to a level higher than that of melt grown samples with x=0.020 in FIG. 5(c) in order to inhibit the precipitation of MnSi in layers, so that the amount of hole carriers was excessive because of V. Hence, it is considered that the addition of Fe, and partial substitution of Mn with Fe for electron doping inhibited increases in hole carriers. As shown in the results in the case of y=0.01 to 0.04, the power factor S²σ increased. In the case of y=0.01 to 0.04, it is considered that an effect of inhibiting the precipitation of MnSi in layers due to increased V was enhanced, so that the power factor S²σ was somewhat higher than that of melt grown samples with x=0.020 in FIG. 5(c). It is considered that because of a state of excessive hole carriers when no Fe (in the case of y=0) was added, the power factor S²σ was somewhat lower than that in the case of y=0.01 to 0.04. Furthermore, it is considered that the addition of Fe at a high level (in the case of y=0.05) increased the amount of doped electrons and made the amount of hole carriers insufficient, so that the power factor S²σ decreased to a level lower than that in the case of y=0.01 to 0.04.

1. A thermoelectric material, containing (Mn_{1-x-y}VₓFe_{y})Si_{σ} (0.012≦x≦0.045, 0≦y≦0.06, and 1.7≦γ≦1.8).

2. The thermoelectric material according to claim 1, wherein a power factor S²σ (where S denotes the Seebeck coefficient, and σ denotes the electrical conductivity) at 700K to 900K is 1.8 mW/K²m or more, and a power factor S²σ at 300K to 1000K is 1.2 mW/K²m or more.

3. The thermoelectric material according to claim 1, wherein a power factor S²σ at 700K to 900K is 2.2 mW/K²m or more, and a power factor S²σ at 300K to 1000K is 1.4 mW/K²m or more.

4. The thermoelectric material according to claim 1, wherein the dimensionless figure of merit ZT (where Z denotes the figure of merit, and T denotes the absolute temperature) at 800K to 900K is 0.55 or more, and the dimensionless figure of merit ZT at 300K to 1000K is 0.15 or more.

5. The thermoelectric material according claim 1, wherein 0.025≦x≦0.045 and 0.01≦y≦0.045.

6. A method for producing the thermoelectric material according to claim 1, comprising:
a melting step for homogeneously melting raw materials including Mn, Si, and V mixed to a composition of said thermoelectric material; and
a solidifying step for solidifying said melted raw materials at a cooling rate of 13K/hour or less.

7. The method for producing the thermoelectric material according to claim 6, wherein said cooling rate is 1.5K/hour or less.
